(19) United States
(12) Patent Application Publication
(10) Pub. No.: US 2009/0128147 A1
(43) Pub. Date: May 21, 2009

(54) NUCLEAR MAGNETIC RESONANCE SPECTROSCOPY WITH MULTIPLE-COIL PROBES

(75) Inventor: Robert Andrew Slade, Cassington (GB)

Correspondence Address: BLANK ROME LLP, WATERGATE, 600 NEW HAMPSHIRE AVENUE, N.W., WASHINGTON, DC, 20037, US

(73) Assignee: Ford Instruments Molecular Biotools Limited, Abingdon, Oxon (GB)

(21) Appl. No.: 12/281,738

(22) PCT Filed: Mar. 13, 2007
(86) PCT No.: PCT/GB2007/000882

§ 371 Date: Nov. 7, 2008

(30) Foreign Application Priority Data
Mar. 13, 2006 (GB) 0605031.4

(51) Int. Cl. G01R 33/30; G01R 33/44

(52) U.S. Cl. 324/309

(57) ABSTRACT

An NMR inspection apparatus comprises a system for providing a dissolved, hyperpolarized sample and an NMR analysis system connected to the hyperpolarizing system are disclosed. The NMR analysis system includes a magnet for generating a substantially homogeneous magnetic field in a working volume suitable for carrying out NMR and a number of RF magnetic field generators located in the working volume. A non-electrically conducting conduit passes adjacent the RF magnetic field generators and is coupled to the hyperpolarizing system so as to convey a hyperpolarized sample past each RF magnetic field generator in sequence. A sample control system controls movement of a sample through the conduit. An NMR signal acquisition system controls the RF magnetic field generators to generate RF magnetic fields in accordance with a predetermined pulse sequence and detects the resulting NMR signals from the portions of the sample exposed to the RF magnetic fields.

### CROSS-REFERENCE TO RELATED APPLICATION

This application is a National Phase Application of PCT/GB2007/000882, filed in the World Intellectual Property Organization (WIPO) on Mar. 13, 2007, which claims the benefit of United Kingdom Patent Application No. 0605031.4, filed in the United Kingdom Intellectual Property Office (UKIPO) on Mar. 13, 2006, which are hereby incorporated by reference.

### FIELD OF THE INVENTION

The present invention relates to an inspection apparatus for inspecting the chemical content of samples using Nuclear Magnetic Resonance (NMR).

### BACKGROUND OF THE INVENTION

There are many well known techniques for obtaining NMR information for chemical analysis from samples. A problem which often occurs is that the NMR signals are very weak, principally because of the poor polarization of the sample in the NMR apparatus. Consequently, various techniques have been developed to hyperpolarize a sample, i.e., to increase the sample's magnetic polarization. A particularly important method of hyperpolarization is Dynamic Nuclear Polarization (DNP) followed by sample dissolution as described, for example, in “Increase in signal-to-noise ratio of >10000 times in liquid-state NMR” Ardenkjaer-Larsen et al., PNAS Vol. 100, Feb. 9, 2003 and WO-A-02/371312. This process, hereinafter referred to as “dissolution DNP”, involves hyperpolarizing the sample in the solid state using DNP and then dissolving it in a hot solvent before moving it rapidly as a liquid into a magnet where an NMR measurement is made. The DNP process typically requires the sample to be cooled to a few Kelvin or below and to be exposed to a strong magnetic field.

To retain significant hyperpolarization, the sample's temperature must be very rapidly raised while in a strong magnetic field. In practice, this means dissolving the sample while still inside the polarization cryostat. This inevitably leads to significant loss of heat from the solvent such that a larger quantity of solvent is required to dissolve the hyperpolarized sample than would be expected from its heat capacity alone. Typically, 4-5 ml of water is required to dissolve a 200 μl sample. This is more than the capacity of a standard 5 mm NMR tube (having a typical capacity of about 0.8 ml) and a significant proportion of the dissolved hyperpolarized sample must be diverted to an overflow vessel where it is not measured, and hence wasted, thereby reducing sensitivity.

A larger, 10 mm NMR tube and probe could be used, in which case the majority of the dissolved sample fits within the tube (having a typical capacity of about 3.6 ml) but only a proportion (about 40%) is within the region of the radio frequency (RF) coil observable volume. Nevertheless, this requires the use of a relatively large RF coil, which also reduces sensitivity. Accordingly, there is a need to be able to achieve the sensitivity of a small coil, such as a micro-coil as found in flow probes, and to measure all the dissolved sample.

### SUMMARY OF THE INVENTION

Accordingly, to solve at least the above problems and/or disadvantages and to provide at least the advantages described below, a non-limiting object of the present invention is to provide an NMR inspection apparatus that comprises a system for providing a dissolved, hyperpolarized sample and an NMR analysis system connected to the hyperpolarizing system; the NMR analysis system including a magnetic field generating means for generating a substantially homogeneous magnetic field in a working volume suitable for carrying out NMR; a number of RF magnetic field generators located in the working volume; a non-electrically conducting conduit passing adjacent the RF magnetic field generators and coupled to the hyperpolarizing system so as to convey a hyperpolarized sample past each RF magnetic field generator in sequence; a sample control system for controlling movement of a sample through the conduit; and an NMR signal acquisition system for controlling the RF magnetic field generators to generate RF magnetic fields in accordance with a predetermined pulse sequence and for detecting the resulting NMR signals from the portions of the sample exposed to the RF magnetic fields.

In accordance with a another object of the present invention, a method of obtaining NMR signals from a dissolved hyperpolarized sample using apparatus according to the first aspect of the invention comprises supplying the hyperpolarized sample to the conduit; moving the sample along the conduit utilizing the sample control system so that portions of the sample are adjacent respective RF magnetic field generators; and operating the NMR signal acquisition system to obtain NMR information from each portion of the sample.

The present invention provides a means to utilize inherently more sensitive RF magnetic field generators, such as micro-coils, with conventional hyperpolarized samples of relatively large volume as provided, for example, by the dissolution-DNP process. Microcoils are small solenoid coils with diameter typically 2-5 mm and length typically 5-15 mm. This is achieved by passing the dissolved sample adjacent a number of RF magnetic field generators in sequence, carrying out the required NMR pulse sequence, and then incrementing the sample to bring fresh, magnetized or polarized portions adjacent the RF magnetic field generators so that a further set of pulse sequences can be carried out. Each individual portion of the sample will be small, typically in the order of 50 to 200 μl.

Movement of the sample could be controlled in a variety of ways, such as by selectively applying a vacuum to the downstream end of the conduit, but is preferably achieved by utilizing a gas pressure generator coupled to the upstream end of the conduit for selectively pressurizing the conduit in order to move the sample to predetermined positions within the conduit.

The RF magnetic generators are preferably solenoids, such as micro-coils, although other coils such as saddle coils could be used.

Any known NMR pulse sequence can be used to inspect the portions of the samples and, in some cases, each sequence will generate a one dimensional NMR spectrum. The pulse sequence applied to each RF generator can be different so that different lines in the indirect direction of a 2D NMR spectrum are obtained from each portion.

As explained in more detail below, the invention is particularly suited for use with more complex pulse sequences, such as that described by Frydman et al. (“The acquisition of multidimensional spectra within a single scan”, PNAS, Vol. 99, Oct. 12, 2002), which can generate two dimensional NMR spectra from a single pulse sequence.

The hyperpolarization system is typically a DNP system although the invention is suitable for use with other hyperpolarization systems such as parahydrogen induced polarization, “brute force” polarization and optically induced polarization.

### BRIEF DESCRIPTION OF THE DRAWINGS

An example of a method and apparatus according to the present invention will now be described with reference to the accompanying drawings, in which:

FIG. 1 shows a schematic view illustrating a non-limiting embodiment of a hyperpolarizing and NMR signal acquisition system according to the present invention;

FIGS. 2A and 2B show a plan view and partial section view, respectively, illustrating the arrangement of microcoils within the NMR probe of the apparatus shown in FIG. 1;

FIGS. 3A-3D illustrate how the flow of a sample is controlled as it passes through the microcoils shown in FIG. 2; and

FIG. 4 show a chart illustrating how a 2D spectrum may be built up from the information obtained by the NMR signal acquisition apparatus.

### DETAILED DESCRIPTION OF THE INVENTION

Reference will now be made in detail to non-limiting embodiments of the present invention by way of reference to the accompanying drawings, wherein like reference numerals refer to like parts, components and structures.

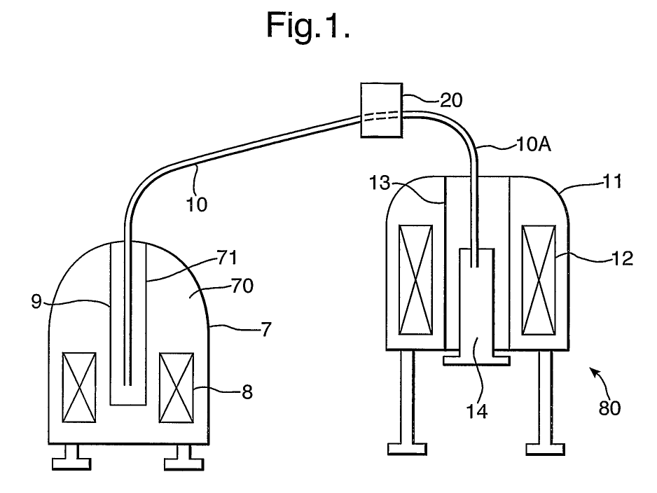

Turning to the Figures, the apparatus shown in FIG. 1 comprises a DNP polarizer system 7, a solvent control system 20, and an NMR magnet assembly 80. The DNP polarizer system 7 includes a cryostat 70 with a cold bore 71 and a superconducting magnet 8 located in the cryostat 70 and surrounding a working volume defined within the bore 71. A DNP insert 9, having an inlet and outlet solvent pipe 10, is located in the cold bore 71 and incorporates a microwave chamber (not shown) in a conventional manner. A sample to be hyperpolarized is placed in the working volume and, following hyperpolarization, is dissolved in a solvent such as water, supplied by a solvent control system 20. The dissolved sample is then flowed along the transfer pipe or conduit 10 formed by a non-electrically conductive material under the control of the solvent control system 20. The flow of the solvent/dissolved sample in FIG. 1 is controlled by application of helium gas pressure from the solvent control system 20 positioned at the upstream end of the conduit 10. Alternatively the flow of solvent/dissolved sample could be controlled by creating a partial downstream vacuum, for example by pumping on the sample tube in the NMR probe 14.

The downstream portion 10A of the conduit passes into a room temperature bore 13 of an NMR magnet assembly 80 comprising a cryostat 11 surrounding a superconducting magnet 12. The magnet 12 defines a homogeneous magnetic field suitable for NMR within a working volume (not shown) within the bore 13. The conduit 110A passes into an NMR probe 14 located in the bore 13.

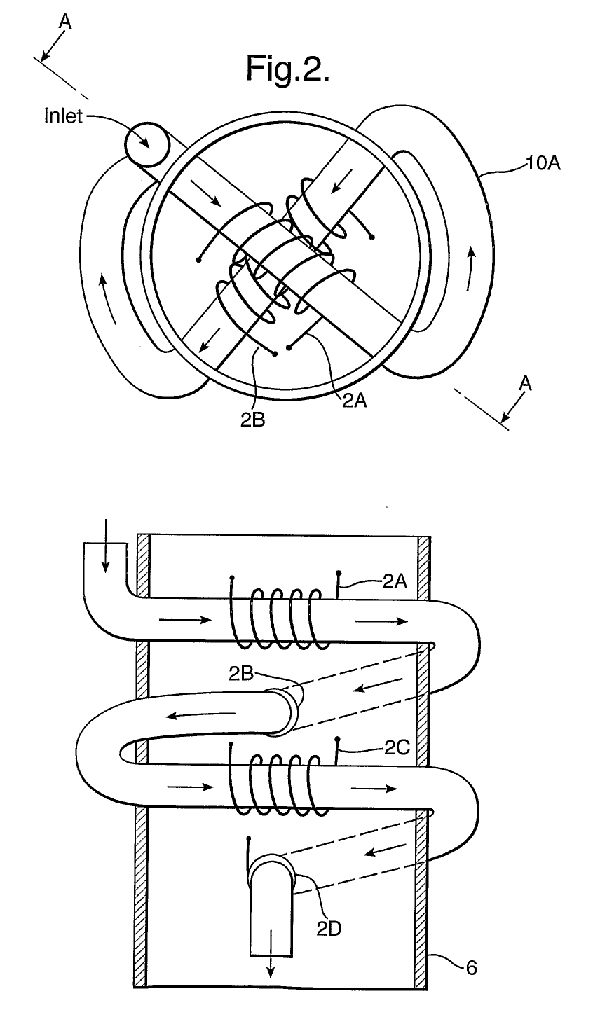

The portion of the NMR probe 14 located in the working volume is shown in more detail in FIGS. 2A and 2B. The probe comprises a cylindrical support 6 which supports the conduit 10A. Four microcoils 2A-2D are wound around respective sections of the conduit 10A, those sections being chosen such that the axes of the coils are perpendicular to the main magnetic field B₀, which extends along the probe and magnet axis (Z)) while adjacent coils along the conduit 10A have their axes orthogonal to each other, i.e., their axes are oriented along the X and Y axes. The coils 2A-2D are sufficiently spaced apart that mutual inductance is minimized.

In some cases, further electric field shielding will be needed to ensure minimal interaction between the coils 2A-2D. In this example, four microcoils 2A-2D are used, but any number are possible in principle although in practice they must all fit within the homogeneous, working region of the main magnetic field.

The conduit 10A passes through each coil 2A-2D in turn, crossing and re-crossing the probes vertical axis, so that subsequent horizontal sections are orthogonal. An important feature of this arrangement is that the connecting loops of the conduit between the coils are arranged such that the RF field from the coils is minimal within those sections of the conduit so that hyperpolarized solution can be stored in those connecting loops while other portions of the sample are being measured using NMR. This is because the connecting loops are outside the influence of the RF field from the coils, so magnetization within them will remain oriented along the static magnetic field B₀. It will continue to relax with a characteristic exponential time constant T1 while stored.

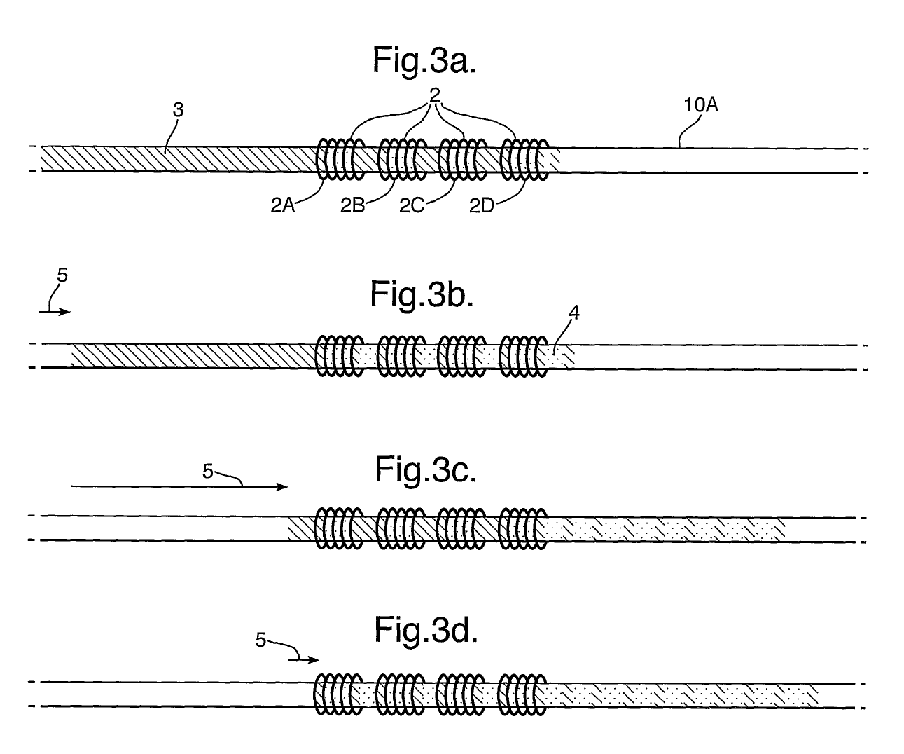

The flow of the sample through the conduit 10A can be stopped and started using gas pressure under the control of the solvent control system 20 so that the column of hyperpolarized sample within the conduit or transfer tube can be shunted forward in controlled steps through the coil set. This process is shown schematically in FIGS. 3A-3D.

FIGS. 3A to 3D depict the hyperpolarized solution position at four subsequent times, just after an NMR measurement has been made. For clarity, the conduit 10A is shown uncoiled in FIGS. 3A to 3D with the RF coils 2A-2D spaced along it at regular intervals. The hyperpolarized magnetization of the solution within the RF coils when an NMR pulse sequence is applied is exhausted by the act of measurement and is shown as dotted shading 4. Unmeasured sample in which the hyperpolarized magnetization is in the longitudinal direction (oriented along B₀) and decaying with characteristic T1 is shown as hatched shading 3. In this example, there are regions of sample in which the magnetization is not sampled. With good instrument design, these regions would be minimized in size to avoid wasting any of the sample.

As explained below, at each position of the sample, the coils 2A-2D are energized to generate predetermined RF magnetic field pulse sequences and are then used to acquire the resultant NMR signals for subsequent processing.

The apparatus can be used to acquire a one dimensional spectrum with increased signal-to-noise ratio (S/N) simply by applying the same pulse sequence to all coils and all samples and co-adding the data. However, the apparatus is preferably used to acquire a two dimensional NMR spectrum. In the simplest form, each line of data in the indirect dimension, which elucidates J-coupling, is acquired by one coil making a measurement on one portion of the sample. The parameter that controls the position of line in the indirect dimension is typically controlled by a change in timing of the pulse sequence. Many such pulse sequences exist, as known to those skilled in the art.

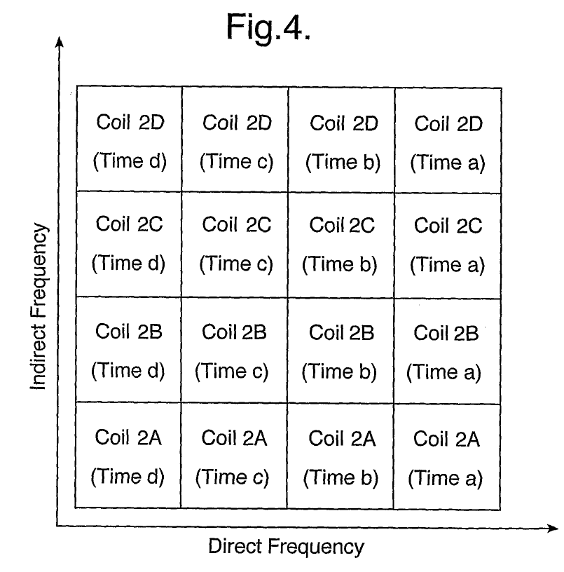

An example of a typical process to acquire a 2D spectrum is set out below.
1. Hyperpolarize frozen sample in polarizer system 7 using DNP.
2. Dissolve sample in minimum quantity of solvent compatible with cryogenic hardware.
3. Flow hyperpolarized solution from polarizer to NMR magnet assembly 80 along transfer pipe 10,10A using helium gas pressure to drive sample flow.
4. Stop flow when solution has entered all measurement coils 2A-2D, at “Time a” (FIG. 4), apply pulse sequence and acquire NMR signal data, the pulse sequence applied to each coil being adjusted to collect a different line in the 2D spectrum.
5. Move solution on to position the unmeasured solution previously between RF coils inside RF coils. Re-apply pulse sequence (with modified parameters, if required) and acquire additional data, at “Time b”.
6. Move solution on again to place fresh magnetization within the RF coils. Re-apply pulse sequence (with modified parameters to select a different set of lines in a 2D sequence) and acquire additional NMR data, at “Time c”.
7. Move solution on once again to position the unmeasured solution between RF coils inside RF coils. Re-apply pulse sequence (with modified parameters, if required) and acquire additional data, at “Time d”.
8. Process NMR data to provide 2D NMR spectrum.

In a preferred embodiment, the pulse sequences are adapted so that the order in which the 2D spectrum is populated maximizes S/N in the final spectrum.

It is important to appreciate that the hyperpolarization of the dissolved sample decays exponentially as it flows along the transfer conduit. The rate of decay, due to spin-lattice relaxation and denoted by T1, depends on the chemical environment of the target atom's nuclei, i.e., on the atoms that the target nucleus is bonded to in the molecule under investigation. Ideally the time taken to transfer the dissolved sample from polarizer to NMR magnet should be much less than the shortest T1 signal, thus minimizing decay. In practice the transfer between separate magnets takes a few seconds. For this reason, the apparatus described by Ardenkjaer-Larsen et al. is more suited to acquiring carbon-13 (¹³C) spectra by direct detection than ¹H (proton) spectra because the proton T1's are short (˜ a few seconds) while the ¹³C T1's are generally in the range 2-60 s. Relaxation rate is also affected by the magnetic field and temperature environment “seen” by the sample during transport. In practice, the transfer time is often similar to the sample's shortest T1 and the hyperpolarization of some target atoms decays significantly during transfer with deleterious effect on S/N.

It is therefore very desirable to collect the rapidly decaying NMR signals from the short T1 atoms first, so as to maximize the S/N of the final spectrum. The fast decaying signals tend to occur at lower frequencies in the spectrum, which is towards the right-hand end of the direct dimension, by convention. It is therefore desirable to collect the subset of the full spectrum containing the fast decaying signals first. These partial spectra are denoted by the boxes marked “Time a” in FIG. 4, which depicts a 2D spectrum. The acquisition of a sub-set of the spectrum is achieved in a modern digital spectrometer by acquiring with a suitable frequency offset and over a narrower bandwidth, as will be understood by those skilled in the art.

This approach requires that several lines, i.e., partial spectra, are acquired simultaneously because practical limitations mean that only a small number of RF coils, e.g., 4, are available. A typical 2D spectrum contains between 64 and 256 lines in the indirect direction. Assuming by way of example 128 lines, then each coil needs to acquire 128/4=32 partial spectra simultaneously. This is possible if a so-called “fast single scan” pulse sequence is used, such as, for example, that described by Frydman et al. (“The acquisition of multidimensional spectra within a single scan”, L. Frydman, S. Tali & A. Lupulescu, PNAS Vol. 99, #25, Oct. 12, 2002).

Frydman's technique utilizes switched magnetic field gradients and swept RF pulses to compartmentalize the sample within a single coil and obtain several spectra in a single multi-echo acquisition using a technique that will be familiar to those skilled in the art of fast MR imaging, e.g., Echo Planar Imaging. These techniques place severe demands on the gradient hardware (rapid switching of strong gradients) and RF hardware (high bandwidth requirement, i.e., very rapid sampling of the signal). This is particularly true for carbon spectra, which cover a very wide frequency range compared to proton spectra (˜300 ppm compared to ˜5 ppm). It is not practical to obtain a whole carbon 1D spectrum, i.e., one whole line in the direct dimension, using his technique with conventional hardware. It is therefore desirable to collect each line in a series of measurements, each covering a narrower frequency band.

The preferred process to acquire a 2D spectrum with optimized SNR in the fast decaying signals is set out below:
1. Hyperpolarize frozen sample in polarizer system 7 using DNP.
2. Dissolve sample in minimum quantity of solvent compatible with cryogenic hardware.
3. Flow hyperpolarized solution from polarizer to NMR magnet assembly 80 along transfer pipe 10,10A using helium gas pressure to drive sample flow. During this time, the hyperpolarization decays exponentially with time constant T1, which depends on molecular environment.
4. Stop flow when solution has entered all measurement coils 2A-2D, at “Time a” (FIG. 4), apply a fast 2D single-scan type pulse sequence to acquire NMR signal data for multiple lines in a 2D spectrum, collecting the frequency band that contains the fastest decaying signals first.
5. Move solution on to position the unmeasured solution previously between RF coils inside RF coils. Re-apply pulse sequence (with modified parameters, if required) and acquire additional data, at “Time b”, to acquire frequency band that contains the second fastest decaying signals.
6. Move solution on again to place fresh magnetization within the RF coils. Re-apply pulse sequence (with modified parameters to select a different set of lines in a 2D sequence) and acquire additional NMR data, at “Time c” (third slowest decaying signal band).
7. Move solution on once again to position the unmeasured solution between RF coils inside RF coils. Re-apply pulse sequence (with modified parameters) and acquire additional data, at “Time d”.
8. Process NMR data to provide 2D NMR spectrum with optimized SNR in short T1 signals.

The NMR data obtained from each coil at each time can be used to build up a full two-dimensional spectrum of the NMR response of the sample as shown in FIG. 4. It should be noted that the frequency bands containing fast decaying signals (short T1s) are acquired first (“Time a”) and those with the slower decaying signals are acquired last (“Time d”). This technique maximizes the overall S/N of the spectrum but reduces the requirement for high bandwidth data collection, i.e., reduced gradient performance is required compared to acquiring the whole 2D-spectrum in a single scan.

The DNP-NMR hardware shown is best suited to NMR measurements on nuclear species having long T1s, such as carbon and nitrogen. Proton T1s are generally too short for this hardware to be useful.

In the preferred embodiment utilizing Frydman-type sequences, the switched magnetic field gradient does not need to be linear, but the resultant field must be single valued across the sample within each coil. It is advantageous that the gradient is in the direction of the long dimension of the sample within the RF coil. In the present invention, alternate solenoid RF coils are arranged at right angles to each other, i.e., along the X and Y axes, for purposes of low coupling (see FIGS. 2A and 2B). The ideal compromise direction for the pulsed gradient is therefore in the XY plane at 45° to the X and Y axes. A conventional X or Y gradient coil, e.g., dB₀z/dx, as described in prior art, encompassing the probe but rotated by 45° around the Z-axis with respect to the RF probe would suffice.

The foregoing description and drawings should be considered as illustrative only of the principles of the invention. The invention may be configured in a variety of shapes and sizes and is not intended to be limited by the preferred embodiment. Numerous applications of the invention will readily occur to those skilled in the art. Therefore, it is not desired to limit the invention to the specific examples disclosed or the exact construction and operation shown and described. Rather, all suitable modifications and equivalents may be resorted to, falling within the scope of the invention.

1. A Nuclear Magnetic Resonance (NMR) inspection apparatus comprising:
a system for providing a dissolved, hyperpolarized sample; and
an NMR analysis system connected to the hyperpolarizing system, the NMR analysis system including:
a magnetic field generating means for generating a substantially homogeneous magnetic field in a working volume suitable for carrying out NMR;
a number of RF magnetic field generators located in the working volume;
a non-electrically conducting conduit passing adjacent the RF magnetic field generators and coupled to the hyperpolarizing system so as to convey a hyperpolarized sample past each RF magnetic field generator in sequence;
a sample control system for controlling movement of a sample through the conduit; and
an NMR signal acquisition system for controlling the RF magnetic field generators to generate RF magnetic fields in accordance with a predetermined pulse sequence and for detecting the resulting NMR signals from the portions of the sample exposed to the RF magnetic fields.

2. An apparatus according to claim 1, wherein the RF magnetic field generators comprise solenoids, the conduit passing in sequence through the bores defined by the solenoids.

3. An apparatus according to claim 2, wherein each RF magnetic field generator is substantially electromagnetically uncoupled with each RF magnetic field generator adjacent thereto along the conduit.

4. An apparatus according to claim 3, wherein the adjacent solenoids are arranged along the conduit with their axes mutually orthogonal.

5. An apparatus according to claim 1, wherein the sample control system comprises a gas pressure generator coupled to the conduit for selectively pressurizing the conduit in order to move the sample to predetermined positions within the conduit.

6. An apparatus according to claim 1, wherein the hyperpolarizing system comprises a Dynamic Nuclear Polarization (DNP) system.

7. A method of obtaining NMR signals from a dissolved, hyperpolarized sample utilizing apparatus according to claim 1, the method comprising:
supplying the hyperpolarized sample to the conduit;
moving the sample along the conduit utilizing the sample control system so that portions of the sample are adjacent respective RF magnetic field generators; and
operating the NMR signal acquisition system to obtain NMR information from each portion of the sample.

8. A method according to claim 7, further comprising operating the sample control system to move the sample along the conduit to bring further portions of the sample from which NMR information has not previously been acquired adjacent respective RF magnetic field generators and repeating the NMR acquisition process.

9. A method according to claim 8, wherein the NMR signal acquisition system is operated to cause the RF magnetic field generators to generate RF magnetic fields simultaneously.

10. A method according to claim 9, wherein the RF magnetic field generators are adapted to implement different pulse sequences so as to obtain respective one dimensional NMR signals from the sample with different offsets in the indirect dimension.

11. A method according to claim 9, wherein the apparatus further comprises means for imposing a magnetic field gradient selectively on the working volume, the RF magnetic field generators being controlled in conjunction with the magnetic field gradient to obtain a two dimensional NMR signal from the sample.

12. A method according to claim 11, wherein the two dimensional NMR signals are obtained using the Frydman et al. technique.

13. A method according to claim 12, wherein the two dimensional NMR signal acquisition pulse sequence is carried out more than once but with reduced bandwidth and successively incremented frequency offset.

14. A method according to claim 12, wherein the two-dimensional NMR signal acquisition pulse sequence is carried out more than once with frequency bands containing fast decaying signals being acquired first and successively slower decaying signals being acquired correspondingly later.

15. A method according to claim 10, further comprising assembling the one dimensional signals to form a two dimensional NMR spectrum of the sample.

16. An apparatus according to claim 1, wherein each RF magnetic field generator is substantially electromagnetically uncoupled with each RF magnetic field generator adjacent thereto along the conduit.

17. A method according to claim 7, wherein the NMR signal acquisition system is operated to cause the RF magnetic field generators to generate RF magnetic fields simultaneously.

18. A method according to claim 7, wherein the RF magnetic field generators are adapted to implement different pulse sequences so as to obtain respective one dimensional NMR signals from the sample with different offsets in the indirect dimension.

19. A method according to claim 7, wherein the apparatus further comprises means for imposing a magnetic field gradient selectively on the working volume, the RF magnetic field generators being controlled in conjunction with the magnetic field gradient to obtain a two dimensional NMR signal from the sample.

20. A method according to claim 11, wherein the two dimensional NMR signal acquisition pulse sequence is carried out more than once but with reduced bandwidth and successively incremented frequency offset.
